(19) United States
(12) Patent Application Publication
(10) Pub. No.: US 2025/0188101 A1
(43) Pub. Date: Jun. 12, 2025

(54) TIN-CONTAINING ASYMMETRIC DONOR MATERIAL AND PREPARATION METHOD AND USE THEREOF

(71) Applicant: Jianghan University, Wuhan (CN)

(72) Inventors: Renqiang YANG, Wuhan (CN); Xunchang WANG, Wuhan (CN); Yirui LIU, Wuhan (CN)

(73) Assignee: Jianghan University, Wuhan (CN)

(21) Appl. No.: 19/053,951

(22) Filed: Feb. 14, 2025

(30) Foreign Application Priority Data
Nov. 27, 2024 (CN) 202411716244.X

(51) Int. Cl. C07F 7/22

(52) U.S. Cl. CPC C07F 7/2208

(57) ABSTRACT

A tin-containing asymmetric donor material has a structural formula as follow:

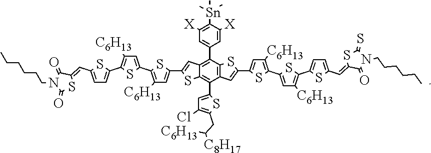

where X represents fluorine or chlorine. The small-molecule tin-containing donor material designed by the present disclosure can form an appropriate energy level difference from an acceptor material L8-BO, which is conducive to the exciton dissociation. In addition, the small-molecule tin-containing donor material exhibits excellent photovoltaic performance in an organic solar cell test. When used in all-small-molecule organic solar cells, the small-molecule tin-containing donor material enables well-defined molecular structures and small batch-to-batch variations for materials and devices. Therefore, the small-molecule tin-containing donor material has unique advantages in commercialization. The small-molecule tin-containing donor material is of great significance for the building of high-efficiency organic solar cell systems.

### CROSS-REFERENCE TO RELATED APPLICATIONS

This application claims priority to Chinese Patent Application No. 202411716244. X with a filing date of Nov. 27, 2024. The content of the aforementioned application, including any intervening amendments thereto, is incorporated herein by reference.

### TECHNICAL FIELD

The present disclosure relates to the technical field of organic optoelectronic materials, and in particular to a tin-containing asymmetric donor material and a preparation method and use thereof.

### BACKGROUND

Tin (Sn), as a metallic element, may be used in the synthesis of semiconductor materials or as a catalyst in the production of batteries in some cases. In particular, tin is commonly used in the study of inorganic solar cells or perovskite solar cells. For example, due to potential cost efficiency and environmental friendliness, tin-based perovskites have become a research focus for replacing lead-based perovskites.

It is proposed that tin is directly introduced into a donor material of an organic solar cell, which belongs to the category of novel material design and is intended optimize the electro-optical characteristics of the donor material through elemental doping or chemical modification. When an organic optoelectronic material is designed, tin (Sn) plays an important role in improving the properties and expanding the functionality for the organic optoelectronic material due to unique electronic properties. Such small-molecule organic donor materials have excellent properties. However, the introduction of tin (Sn) is also faced with challenges, such as increase in synthesis difficulty and cost, and poor environmental friendliness. Therefore, when organic optoelectronic materials are designed, these factors need to be weighed. In addition, when organic optoelectronic materials are constructed, a molecular structure with F and Cl groups will be designed to acquire desired optoelectronic properties, stability, and prominent processability. This molecular structure can enhance the electron affinity of molecules and reduce the highest occupied molecular orbital (HOMO) energy level or increase the lowest unoccupied molecular orbital (LUMO) energy level, thereby affecting the energy band structure of a material. Therefore, the molecular structure is critical for the electron and hole transport in organic semiconductor materials such as organic photovoltaic cells and organic light-emitting diodes (OLEDs), and can optimize the injection, transport, and recombination efficiencies of carriers.

### SUMMARY OF PRESENT INVENTION

An objective of the present application is to provide a tin-containing asymmetric donor material and a preparation method and use thereof, so as to optimize the optoelectronic properties of the material and meet the needs of specific applications.

An embodiment of the present application provides a tin-containing asymmetric donor material with a structural formula shown in formula 1:

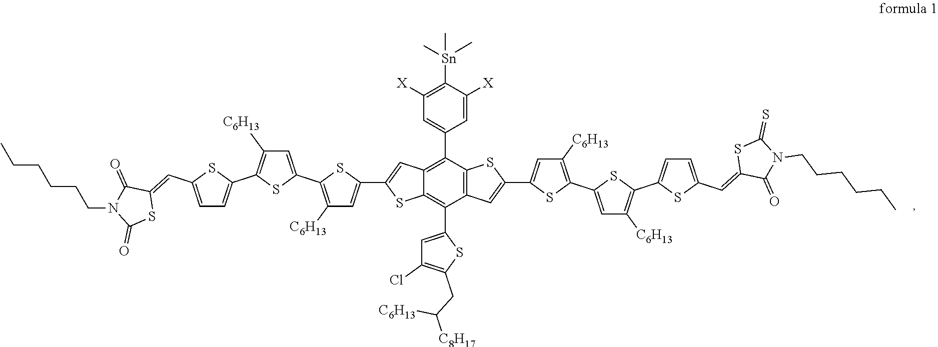

where X represents fluorine or chlorine.

A preparation method of the tin-containing asymmetric donor material is provided, including the following specific steps:
step 1, with tetrahydrofuran as a solvent and iodine as an initiator, adding a magnesium powder and 4-bromo-1,2-difluorobenzene to produce a first mixture, making the first mixture under reflux at 70° C. for 4 h until magnesium is completely consumed, and naturally cooling to room temperature to produce a first Grignard reagent; adding the first Grignard reagent dropwise to a solution of benzo[1,2-b: 4,5-b′]dithiophene-4,8-dione in toluene, and stirring at room temperature to produce a mixed solution; with tetrahydrofuran as a solvent and iodine as an initiator, adding a magnesium powder and 5-bromo-3-chloro-2-(2-hexyldiethyl) thiophene to produce a second mixture, making the second mixture under reflux at 70° C. for 2 h until magnesium is completely consumed, and naturally cooling to room temperature to produce a second Grignard reagent; transferring the second Grignard reagent into a dropping funnel, slowly adding the second Grignard reagent dropwise to the mixed solution, and stirring overnight at room temperature; adding tin (II) chloride dihydrate dissolved in HCl with a mass concentration of 10% at room temperature, further stirring at 50° C. for 3 h, and naturally cooling to room temperature to produce a reaction product; and pouring the reaction product into water, which is a compound (1);
step 2, under argon protection and at −78° C., adding a n-butyllithium solution dropwise to a solution of the compound (1) in tetrahydrofuran; stirring at −78° C. for 1 h; adding the compound (1), and stirring at −78° C. for 1 h; naturally warming to room temperature, and allowing a reaction for 12 h to produce a third mixture; cooling the third mixture to room temperature, adding a tin reagent solution, and further stirring at 50° C. for 3 h to produce a compound (2);
step 3, under argon protection, with tetrakis (triphenylphosphine) palladium as a catalyst and toluene as a solvent, subjecting the compound (2) obtained in the step 2 to a Stille coupling reaction with 5″-bromo-3′,3″-dihexyl-[2,2′:5′,2″-trithiophene]-5-carbaldehyde under reflux at 110° C. for 8 h to 10 h to produce a compound (3); and

step 4, under argon protection, adding the compound (3), 3-hexylrhodanine, and an alkali to trichloromethane as a solvent, and conducting a Knoevenagel condensation reaction at 60° C. for linking a rhodanine end-capping group to produce a small-molecule organic donor material with asymmetric two-dimensional side chains.

Further, in the step 1, the 5-bromo-3-chloro-2-(2-hexyldiethyl) thiophene, the 4-bromo-1,2-difluorobenzene, and the benzo[1,2-b: 4,5-b′]dithiophene-4,8-dione are in an amount ratio of 1:2:5; and an amount ratio of the benzo[1,2-b: 4,5-b′]dithiophene-4,8-dione to the tin (II) chloride dihydrate is 1:5.

Further, in the step 2, the tin reagent solution is a solution of chlorotrimethylstannane dissolved in tetrahydrofuran (THF) with a concentration of 1.0 M; an amount ratio of the compound (1) to the chlorotrimethylstannane is 1:3; and an amount ratio of n-butyllithium to the compound (1) is 1:3.5.

Further, in the step 3, the Stille coupling reaction under reflux is conducted for preferably 9 h; an amount ratio of the compound (2) to the 5″-bromo-3′,3″-dihexyl-[2,2′:5′,2″-trithiophene]-5-carbaldehyde is 1:15; and an amount ratio of the catalyst to the compound 3 is 20 mg: 8.69 mmol.

Further, in the step 4, the alkali is piperidine; the Knoevenagel condensation reaction is conducted for 24 h; an amount ratio of the 3-hexylrhodanine to the compound (4) is 15:1; and an amount ratio of the alkali to the compound (4) is 1.5 mL: 0.592 mmol.

A use of the tin-containing asymmetric donor material in preparation of an organic optoelectronic device is provided.

Further, the organic optoelectronic device is able to be used in preparation of a solar cell, OLED, and a flexible display.

Beneficial effects of the present disclosure: The small-molecule tin-containing donor material designed by the present disclosure can form an appropriate energy level difference from an acceptor material L8-BO, which is conducive to the exciton dissociation. In addition, the small-molecule tin-containing donor material exhibits excellent photovoltaic performance in an organic solar cell test. According to an actual situation, a content of tin can be appropriately controlled during the synthesis to ensure the improvement of properties of the material, the feasibility and economy of the synthesis, and the prominent intermolecular packing effect, which is conducive to the improvement of charge mobility.

In an organic optoelectronic material, a structure of a tin (Sn)-containing compound can be adjusted to effectively adjust the HOMO and LUMO energy levels of the material, thereby optimizing the photovoltaic efficiency.

### BRIEF DESCRIPTION OF THE DRAWINGS

FIG. 1 is a proton nuclear magnetic resonance (¹H NMR) spectrum of the compound 1 prepared in the present disclosure (deuterated chloroform, 400 MHZ);

FIG. 2 is a ¹H NMR spectrum of the compound 2 prepared in the present disclosure (deuterated chloroform, 400 MHz);

FIG. 3 is a ¹H NMR spectrum of the compound 3 prepared in the present disclosure (deuterated chloroform, 400 MHz);

FIG. 4 is a ¹H NMR spectrum of the compound Z2-Sn prepared in Example 1 of the present disclosure (deuterated chloroform, 400 MHZ);

FIG. 5 is a Tin nuclear magnetic resonance (Sn NMR) spectrum of the compound Z2-Sn prepared in Example 1 of the present disclosure (deuterated chloroform, 400 MHz);

FIG. 6 shows J-V curves of an organic photovoltaic device prepared by blending the compound Z2-Sn of Example 1 of the present disclosure with L8-BO in a mass ratio of 1.2:1 and an organic photovoltaic device prepared by blending PM6 and L8-Bo in a mass ratio of 1.2:1 that are measured under one simulated sunlight;

FIG. 7 shows electrochemical cyclic voltammetry curves of an organic photovoltaic device prepared by blending the compound Z2-Sn of Example 1 of the present disclosure with L8-BO in a mass ratio of 1.2:1; and

FIG. 8 shows ultraviolet-visible absorption spectra of the solution and the film in Example 1 of the present disclosure that are determined with a Hitachi U-4100 spectrophotometer.

### DETAILED DESCRIPTION OF THE EMBODIMENTS

The technical solutions of the examples of the present disclosure are clearly and completely described below with reference to the accompanying drawings in the examples of the present disclosure. Apparently, the examples are merely some rather than all of the examples of the present disclosure. All other examples obtained by those of ordinary skill in the art based on the examples of the present disclosure without creative efforts should fall within the protection scope of the present disclosure.

In the following examples, unless otherwise specified, “water” used is deionized water.

### Example 1 Synthesis of a compound Z2-Sn

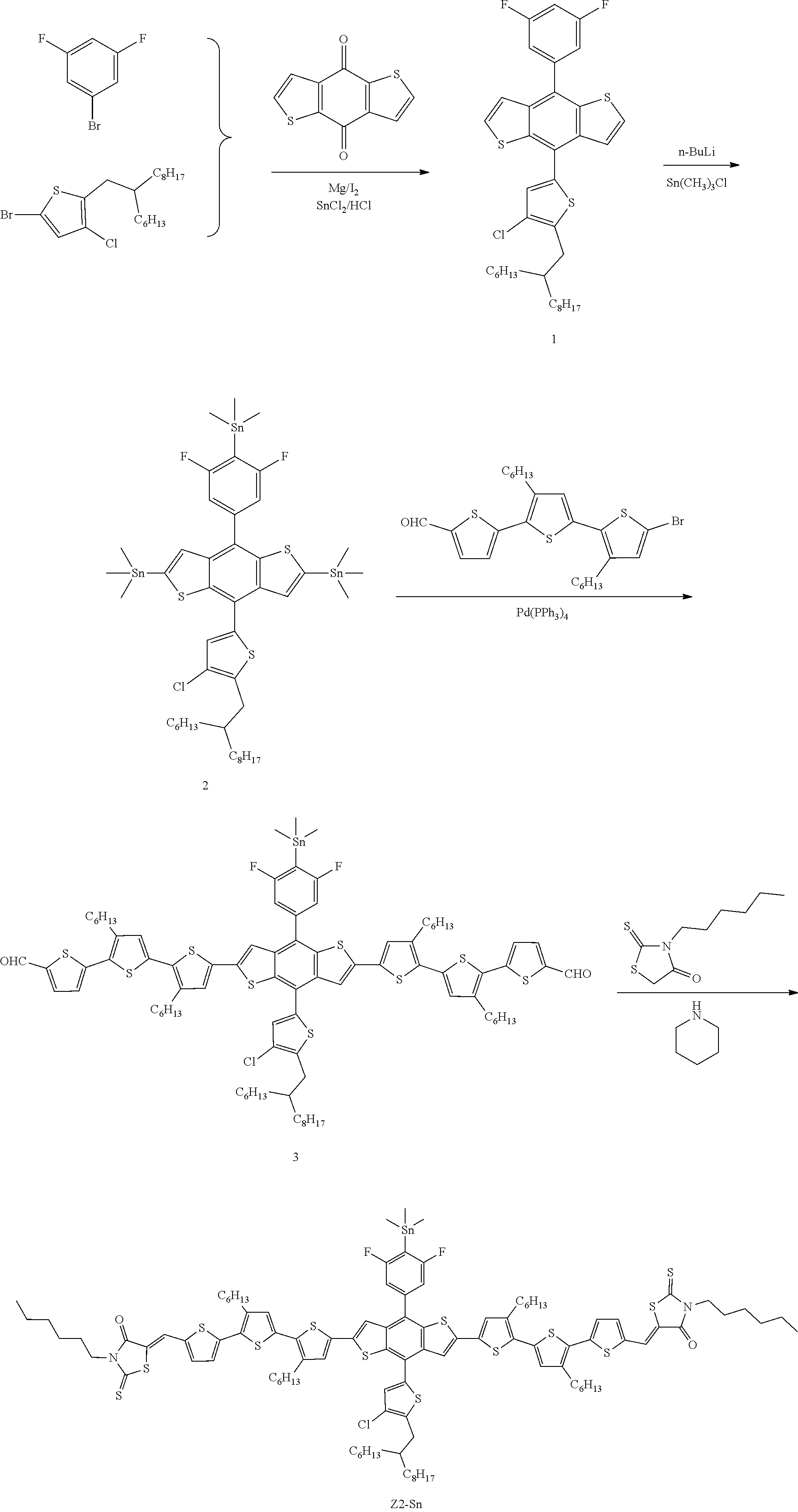

### Synthesis of a Compound 1:

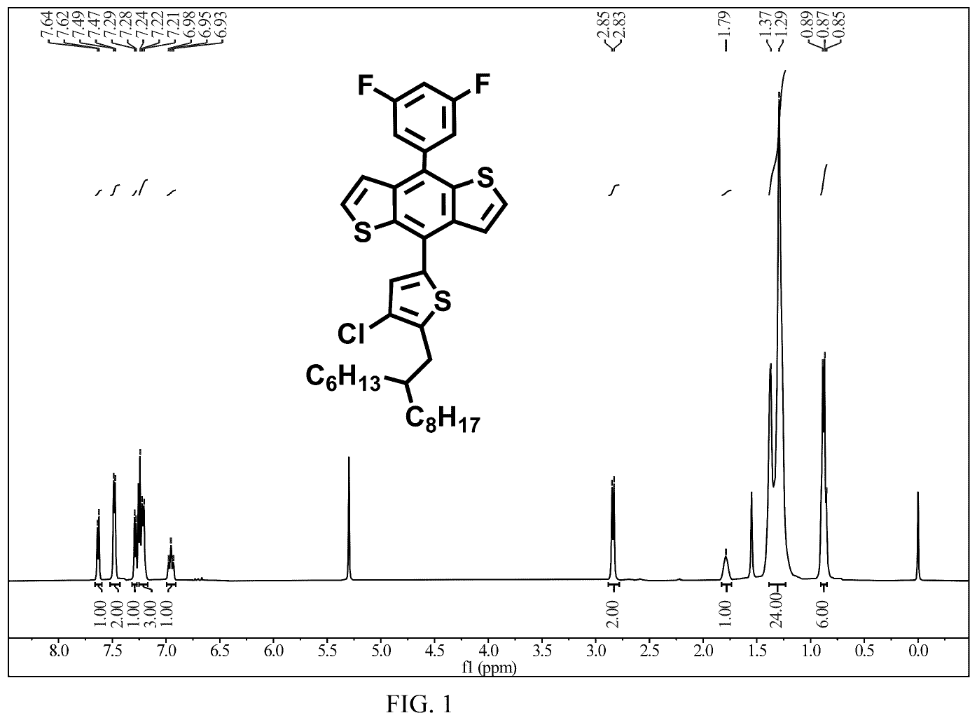

1-bromo-3-chloro-5-fluorobenzene (47.38 mmol) and a magnesium powder (56.87 mmol) were added to a first round-bottomed flask filled with repeatedly-distilled tetrahydrofuran (50 mL). Then iodine (20 mg) was added as an initiator to the first round-bottomed flask to produce a first mixture. The first mixture was allowed to be under reflux at 70° C. for 4 h until magnesium was completely consumed, and then naturally cooled to room temperature (25° C., the same below) to produce a first Grignard reagent. The first Grignard reagent was then transferred into a dropping funnel and slowly added dropwise (30 drops/min) to 150 mL of a solution of benzo[1,2-b: 4,5-b′]dithiophene-4,8-dione (118.45 mmol) in toluene to produce a mixed solution. 5-bromo-3-chloro-2-(2-hexyldecyl) thiophene (23.69 mmol) and a magnesium powder (28.43 mmol) were added to a second round-bottomed flask filled with repeatedly-distilled tetrahydrofuran (50 mL). Then iodine (20 mg) was added as an initiator to the second round-bottomed flask to produce a second mixture. The second mixture was allowed to be under reflux at 70° C. for 2 h until magnesium was completely consumed, and then naturally cooled to room temperature (25° C., the same below) to produce a second Grignard reagent. The second Grignard reagent was transferred into a dropping funnel and slowly added dropwise (30 drops/min) to the mixed solution, and stirring was conducted overnight at room temperature. Then tin (II) chloride dihydrate (710.7 mmol) dissolved in HCl (15 mL) with a mass concentration of 10% was added to produce a third mixture, and the third mixture was further stirred at 50° C. for 3 h, naturally cooled to room temperature, and poured into water to produce an organic matter. The organic matter was extracted 3 times with dichloromethane and then dried with anhydrous sodium sulfate, and the solvent was removed by a rotary evaporator to produce a crude product. The crude product was purified by silica gel column chromatography (eluent: petroleum ether) to produce a light-white solid compound 1 (yield: 63%), which was 4-(4-chloro-5-(2-hexyldecyl)thiophene-2-yl)-8-(3-chloro-5-fluorophenyl)benzo[1,2-b: 4,5-b′]dithiophene. A 1H NMR spectrum of the compound 1 was shown in FIG. 1.

### Synthesis of a Compound 2

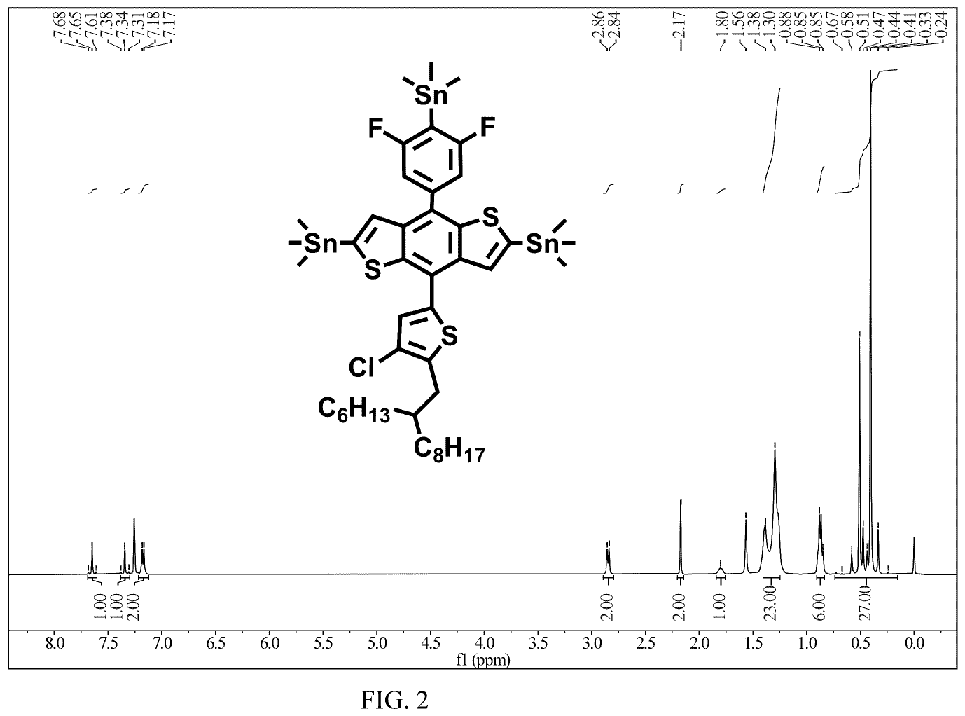

Under argon protection and at −78° C., n-butyllithium (53.17 mmol, 1.6 M) was added dropwise (30 drops/min) to a solution (60 mL) of the compound 1 (15.19 mmol) in tetrahydrofuran, and stirring was conducted at −78° C. for 1 h. Then a solution of trimethyltin chloride in tetrahydrofuran (45.57 mmol, 1 M) was added to produce a mixed system, and the mixed system was stirred at −78° C. for 1 h, then naturally warmed to room temperature, stirred at room temperature for 12 h, and poured into deionized water. Extraction was conducted three times with anhydrous diethyl ether (50 mL each time). Drying was conducted with anhydrous sodium sulfate, and The solvent was removed by a rotary evaporator to produce a crude product. The crude product was subjected to recrystallization in toluene (operation steps for the recrystallization were as follows: 50 mL of toluene was added to the crude product to produce a mixture, the mixture was heated to 55° C. to 60° C. to dissolve the crude product, naturally cooled to room temperature, and allowed to stand for 5 h to produce a crystallized product, and the crystallized product was collected through filtration, the same below) twice to produce a yellow solid compound 2 (a yield in this step was 80%). A 1H NMR spectrum of the compound 2 was shown in FIG. 2.

### Synthesis of a Compound 3

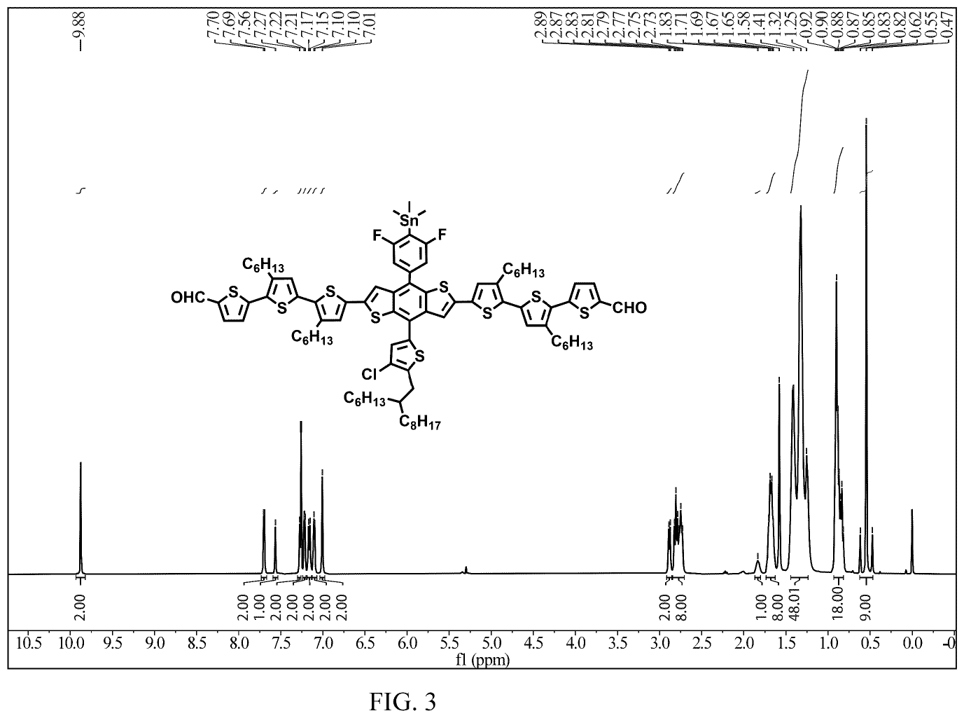

Under argon protection, the compound 2 (8.69 mmol), 5″-bromo-3′,3″-dihexyl-[2,2′:5′,2″-trithiophene]-5-carbaldehyde (130.43 mmol), and tetrakis (triphenylphosphine) palladium (20 mg) were added to a round-bottomed flask, and then anhydrous toluene (30 mL) was added to the round-bottomed flask to produce a reaction system. The reaction system was stirred at 110° C. for 9 h, naturally cooled to room temperature, and quenched with deionized water to produce an organic matter. The organic matter was extracted with dichloromethane 3 times (50 mL each time), and then dried with anhydrous sodium sulfate. The solvent was removed by a rotary evaporator to produce a crude product. The crude product was purified by silica gel column chromatography (eluent: dichloromethane) to produce a red solid compound 3 (a yield in this step was 48%). A ¹H NMR spectrum of the compound 3 was shown in FIG. 3.

### Synthesis of a Compound Z2-Sn

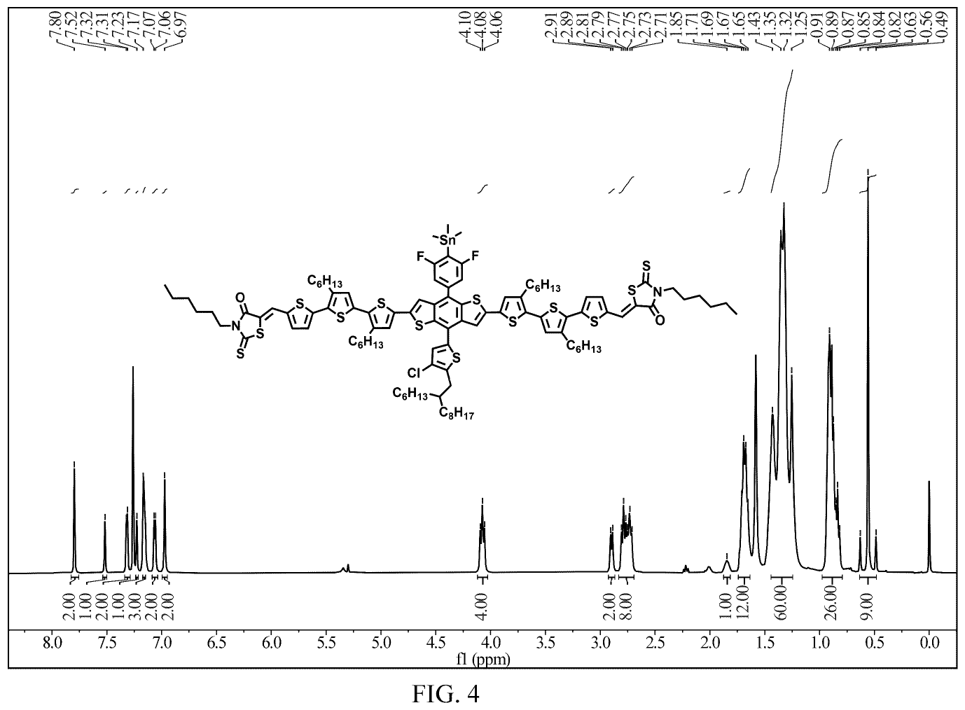

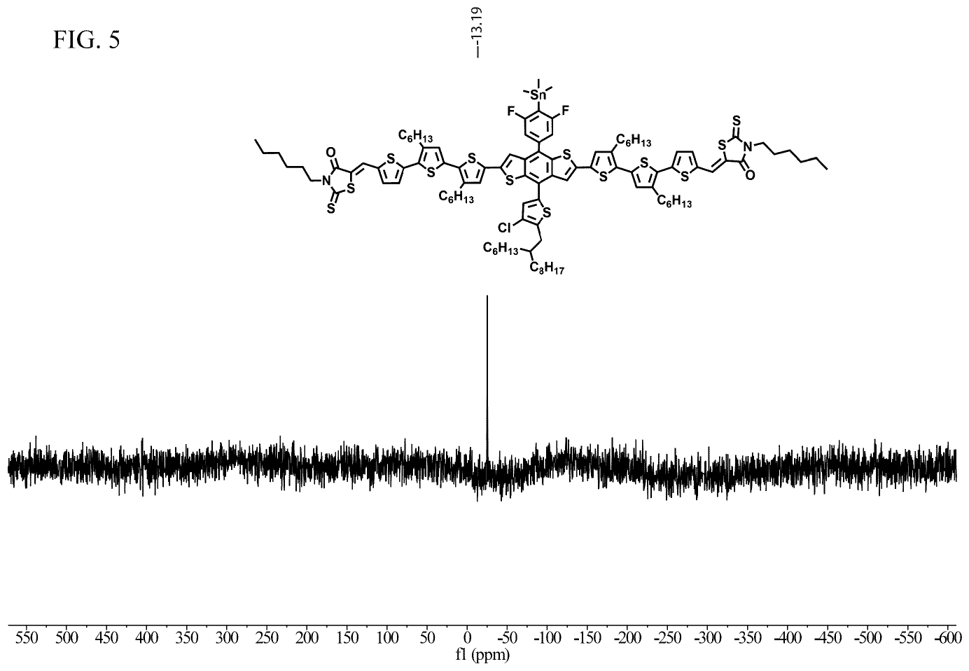

Under argon protection, the compound 3 (0.592 mmol), 3-hexylrhodanine (8.88 mmol), and 0.1 mL of piperidine were dissolved in dry trichloromethane (15 mL) to produce a reaction system. The reaction system was stirred at 60° C. for 24 h, naturally cooled to room temperature, and then quenched with deionized water. Extraction was conducted three times with trichloromethane (50 mL each time), and then the solvent was removed by a rotary evaporator to produce a crude product. The crude product was purified by silica gel column chromatography (eluent: a mixture of petroleum ether and trichloromethane in a volume ratio of 1:1) to produce a red solid compound Z2-Sn (a yield in this step was 65%), which was the required small-molecule organic donor material with two fluorine atoms: the compound Z2-Sn. A ¹H NMR spectrum of the compound Z2-Sn was shown in FIG. 4, and a ¹³C NMR spectrum of the compound Z2-Sn was shown in FIG. 5.

### Example 2 Characterization of All-Small-Molecule Organic Solar Cells

An organic photovoltaic device was prepared with the compound Z2-Sn prepared in Example 1 as a donor material and an acceptor material L8-BO, and specific steps were as follows:
(1) An indium tin oxide (ITO) conductive glass was ultrasonically cleaned, treated with oxygen-Plasma, first spin-coated with poly(3,4-ethylenedioxythiophene) (PEDOT): poly(styrenesulfonate) (PSS) (a ratio: 1:1, a mixed solution prepared at the time of purchase) at 5,000 rpm, and then annealed at 150° C. for 15 min to produce a substrate with a surface film thickness of about 40 nm.
(2) Then the small-molecule compound Z2-Sn prepared in Example 1 as a donor material was mixed with an acceptor L8-BO (with a structural formula shown below), and a mixed solvent of diiodomethane and trichloromethane (a volume ratio of the diiodomethane to the trichloromethane was 0.3 μL: 100 μL) was added to prepare a blended solution (a total concentration of the donor and the acceptor was 20 mg/mL, and a mass ratio of the donor to the acceptor was 1.2:1). The blended solution was spin-coated at 2,000 rpm on the substrate obtained in the step (1) to form an active layer with a thickness of about 130 nm on a surface of the substrate.
(3) A substrate with the active layer obtained in the step (2) was placed in a 60 nm Petri dish, 60 μL of chlorobenzene was evenly applied on surfaces of the substrate, and then solvent vapor annealing was conducted (85° C., 5 min). Then a PNDIT-F3N film as an electron transport layer was spin-coated on the active layer at 3,000 rpm, with a film thickness of about 10 nm. Finally, a silver layer with a thickness of 100 nm was deposited on the electron transport layer through vapor deposition.

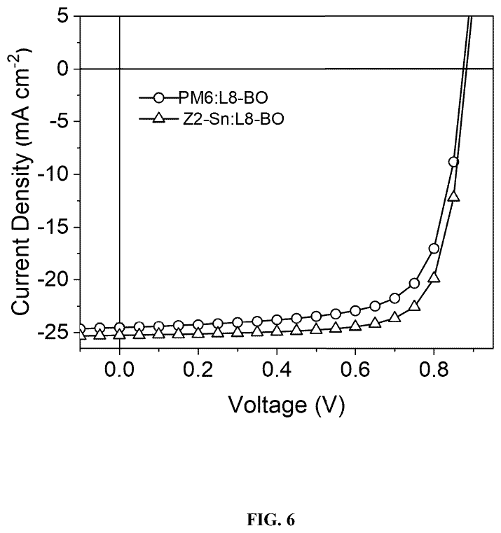

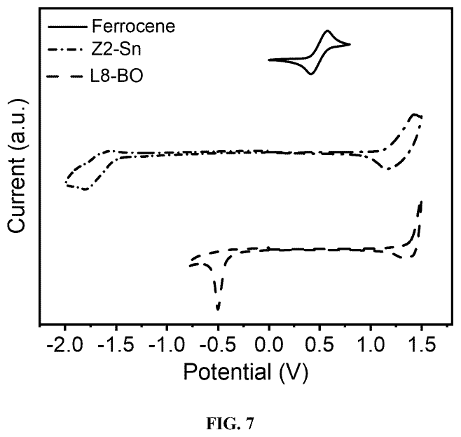

Specific performance parameters of solar cells were shown in Table 1 and FIG. 6 to FIG. 7.

A device used in the laboratory of the present disclosure was a solar simulator, which was calibrated with a silicon solar cell. All tests were conducted under one simulated sunlight, 100 mW/cm².

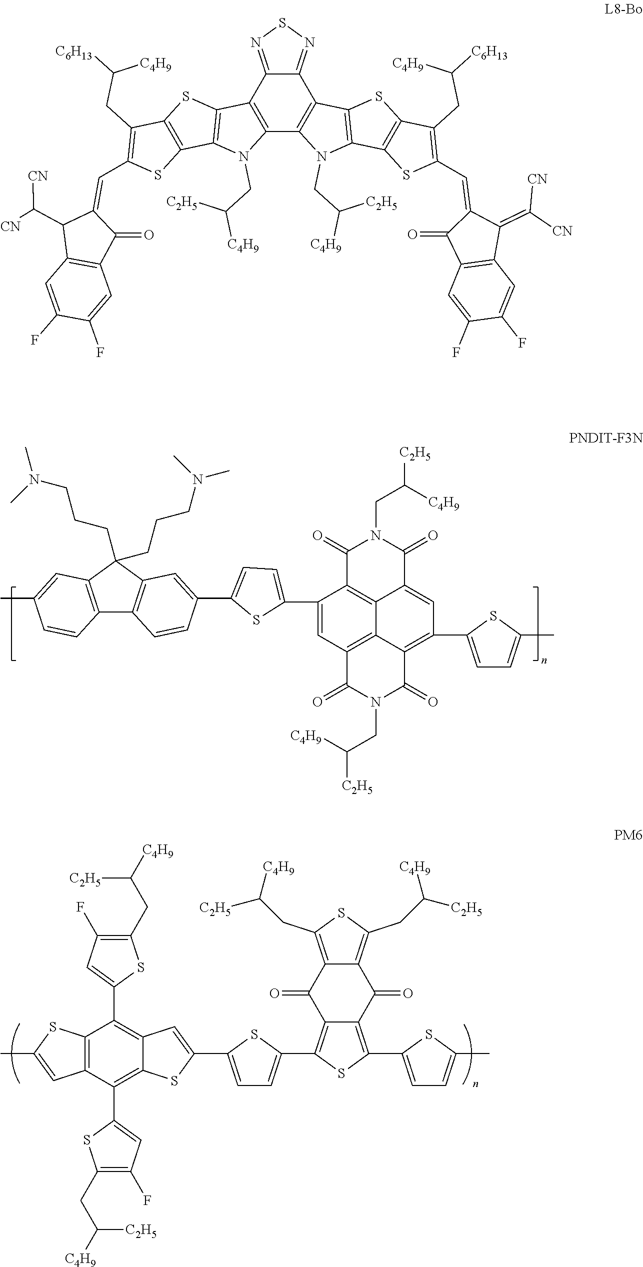

TABLE 1
Photoelectric conversion efficiencies (PCEs)
of all-small-molecule photovoltaic devices

| Donor | V_{oc} (V) | J_{sc} (mA/cm²) | FF (%) | PCE (%) |
|---|---|---|---|---|
| PM6:L8-Bo | 0.87 | 24.80 | 73.08 | 16.13 |
| Z2-Sn:L8-Bo | 0.88 | 25.25 | 75.94 | 16.93 |

It can be seen from the data in Table 1 and the J-V curves in FIG. 6 that, compared with PM6:L8-Bo, PM6:Z2-Sn:L8-Bo has significantly-improved PCE, a fill factor (FF) increased from 73.08% to 75.94%, and J_{sc} (a current density) increased from 24.80 mA/cm² to 25.25 mA/cm². This is because a blend of the compound Z2-Sn and the L8-BO has a larger exciton diffusion coefficient and a faster exciton dissociation process than a blend of the compound PM6 and the L8-BO.

When used in all-small-molecule organic solar cells, the small-molecule compound enables well-defined molecular structures and small batch-to-batch variations for materials and devices. Therefore, the small-molecule compound has unique advantages in commercialization. The small-molecule compound is of great significance for the building of high-efficiency organic solar cell systems.

It can be seen from FIG. 7 that the compound Z2-Sn has an HOMO energy level of −5.04 eV and an LUMO energy level of −2.77 eV, and can form an appropriate energy level difference from L8-BO, which is conducive to the exciton dissociation and can improve the PCE of a photovoltaic device.

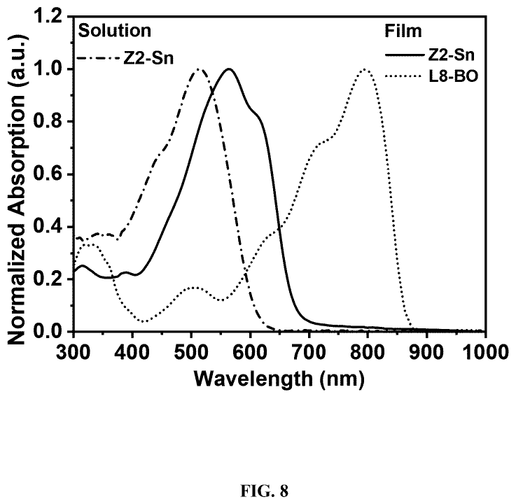

As shown in FIG. 8, ultraviolet-visible absorption spectra of a solution and a film were determined with a Hitachi U-4100 spectrophotometer. Determination of absorption spectra of the solution: A test sample was dissolved in chloroform at a concentration of 0.01 mg/mL and tested at room temperature. Determination of absorption spectra of the film: A chloroform solution of the test sample (5.0 mg/mL, 1,500 rpm) was spin-coated on a quartz plate to form the film, and then the film was tested. It can be seen from FIG. 8 that the compound Z2-Sn has a prominent intermolecular packing effect, which contributes to the improvement of charge mobility.

In the present application, a brand-new small-molecule donor material is designed and synthesized by introducing both a benzene ring and thiophene into a small-molecule donor material and introducing tin on two-dimensional side chains. The brand-new small-molecule donor material allows PCE of 16.93%, and has an important application prospect in binary all-small-molecule organic solar cells.

It is apparent for those skilled in the art that the present disclosure is not limited to details of the above exemplary embodiments, and that the present disclosure may be implemented in other specific forms without departing from the spirit or basic features of the present disclosure. Accordingly, the embodiments should be regarded in all points of view as exemplary and not restrictive, and the scope of the present disclosure is defined by the appended claims rather than the above description. Therefore, all changes falling within the meaning and scope of equivalent elements of the claims should be included in the present disclosure. Any reference numerals in the claims should not be considered as limiting the involved claims.

What is claimed is:

1. A tin-containing asymmetric donor material with a structural formula shown in formula 1: 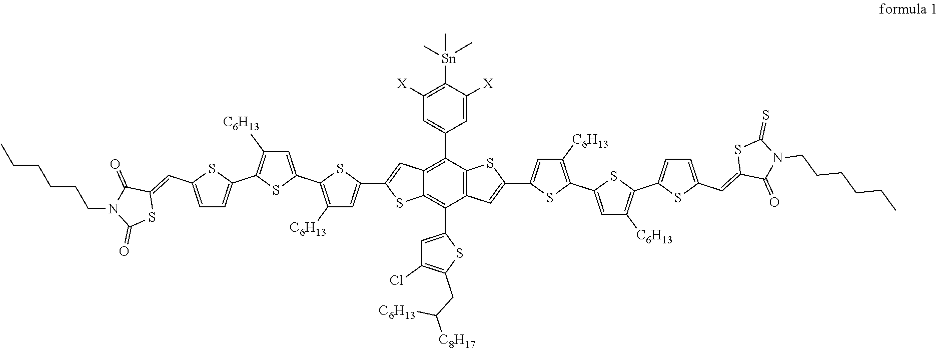
wherein X represents fluorine or chlorine.

2. A preparation method of the tin-containing asymmetric donor material according to claim 1, comprising the following specific steps:
step 1, with tetrahydrofuran as a solvent and iodine as an initiator, adding a magnesium powder and 4-bromo-1,2-difluorobenzene to produce a first mixture, making the first mixture under reflux at 70° C. for 4 h until magnesium is completely consumed, and naturally cooling to room temperature to produce a first Grignard reagent; adding the first Grignard reagent dropwise to a solution of benzo[1,2-b: 4,5-b′]dithiophene-4,8-dione in toluene, and stirring at room temperature to produce a mixed solution; with tetrahydrofuran as a solvent and iodine as an adding initiator, a magnesium powder and 5-bromo-3-chloro-2-(2-hexyldecyl)thiophene to produce a second mixture, making the second mixture under reflux at 70° C. for 2 h until magnesium is completely consumed, and naturally cooling to room temperature to produce a second Grignard reagent; transferring the second Grignard reagent into a dropping funnel, slowly adding the second Grignard reagent dropwise to the mixed solution, and stirring overnight at room temperature; adding tin (II) chloride dihydrate dissolved in HCl with a mass concentration of 10% at room temperature, further stirring at 50° C. for 3 h, and naturally cooling to room temperature to produce a reaction product; and pouring the reaction product into water, which is a compound (1);
step 2, under argon protection and at −78° C., adding a n-butyllithium solution dropwise to a solution of the compound (1) in tetrahydrofuran; stirring at −78° C. for 1h; naturally warming to room temperature, and allowing a reaction for 12 h to produce a third mixture; cooling the third mixture to room temperature, adding a tin reagent solution, and further stirring at 50° C. for 3 h to produce a compound (2);
step 3, under argon protection, with tetrakis (triphenylphosphine) palladium as a catalyst and toluene as a solvent, subjecting the compound (2) obtained in the step 2to a Stille coupling reaction with 5″-bromo-3′,3″-dihexyl-[2,2′:5′,2″-trithiophene]-5-carbaldehyde under reflux at 110° C. for 8 h to 10 h to produce a compound (3); and
step 4, under argon protection, adding the compound (3), 3-hexylrhodanine, and an alkali to trichloromethane as a solvent, and conducting a Knoevenagel condensation reaction at 60° C. for linking a rhodanine end-capping group to produce a small-molecule organic donor material with asymmetric two-dimensional side chains.

3. The preparation method according to claim 2, wherein in the step 1, the 5-bromo-3-chloro-2-(2-hexyldiethyl)thiophene, the 4-bromo-1,2-difluorobenzene, and the benzo[1,2-b: 4,5-b′]dithiophene-4,8-dione are in an amount ratio of 1:2:5; and an amount ratio of the benzo[1,2-b: 4,5-b′]dithiophene-4,8-dione to the tin (II) chloride dihydrate is 1:5.

4. The preparation method according to claim 2, wherein in the step 2, the tin reagent solution is a solution of chlorotrimethylstannane dissolved in tetrahydrofuran (THF) with a concentration of 1.0 M; an amount ratio of the compound (2) to the chlorotrimethylstannane is 1:3; and an amount ratio of n-butyllithium to the compound (1) is 1:3.5.

5. The preparation method according to claim 2, wherein in the step 3, the Stille coupling reaction under reflux is conducted for preferably 9 h; an amount ratio of the compound (3) to the 5″-bromo-3′,3″-dihexyl-[2,2′:5′,2″-trithiophene]-5-carbaldehyde is 1:15; and an amount ratio of the catalyst to the compound (2) is 20 mg: 8.69 mmol.

6. The preparation method according to claim 2, wherein in the step 4, the alkali is piperidine; the Knoevenagel condensation reaction is conducted for 24 h; an amount ratio of the 3-hexylrhodanine to the compound (3) is 15:1; and an amount ratio of the alkali to the compound (3) is 1.5 mL: 0.592 mmol.
